(19) United States
(12) Patent Application Publication
(10) Pub. No.: US 2007/0284671 A1
(43) Pub. Date: Dec. 13, 2007

(54) SEMICONDUCTOR DEVICE INCLUDING CMIS TRANSISTOR

(75) Inventors: Toshiaki TSUTSUMI, Tokyo (JP); Tomonori Okudaira, Tokyo (JP); Keiichiro Kashihara, Tokyo (JP); Tadashi Yamaguchi, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/759,564

(22) Filed: Jun. 7, 2007

(30) Foreign Application Priority Data
Jun. 13, 2006 (JP) 2006-163531

(51) Int. Cl. H01L 29/94; H01L 21/8238

(52) U.S. Cl. 257/369; 438/199; 257/E27.062

(57) ABSTRACT

Gate electrodes made of polysilicon film are isolated and face each other by way of a side wall spacer portion that fills a gap formed above an isolation insulating film at the boundary of NMIS region and PMIS region. A first metal film is formed on one of the gate electrodes, and an inhomogeneous second metal film is formed on the other of the gate electrodes. The both gate electrodes become inhomogeneous metal silicide gates through the promotion of silicide reaction by heat treatment. The mutual diffusion of metal atoms from the metal film to the gate electrode is suppressed by the interposition of the side wall spacer portion being an insulating film.

### BACKGROUND OF THE INVENTION

1. Field of the Invention

The present invention relates to the field of semiconductor devices including a CMIS transistor.

2. Description of the Background Art

A stacked configuration of polysilicon and metal silicide has been conventionally used for the gate electrode material in response to the demand for workability and heat resistance, and easiness in threshold control of the CMIS.

However, a configuration configured only from metal or metal silicide is again given attention for the gate material for higher performance of the transistor, lower resistance of the gate electrode, and suppression of gate depletion in the logic device of 45 nm or over, and is recently being actively researched and developed.

In addition to lower temperature of the process in response to the demands for enhancing the performance of the transistor, and enhancement in lithography and dry etching techniques, enhancement in the new processing technique using the CMP (Chemical Mechanical Polishing) also contributes greatly to the realization of the pattern formation of such gate electrode configuration.

The dual gate must be adopted for the threshold value control of the CMIS, which is a large problem, and different materials must be used to obtain different threshold values for NMIS and PMIS transistors, and a method of forming the transistors of both conductivity type is being actively researched.

Japanese Laid-Open Patent Publication No. 2005-167251 describes a method of forming different silicide films, and proposes a method of using different metal silicide materials or silicide materials of the same metal but different composition for the NMOS region and the PMOS region using the reaction between metal and silicon.

A method of using the metal film for the gate electrode is described in JaeHoon Lee et al. “Tunable Work Function Dual Metal Gate Technology for Bulk and Non-Bulk CMOS”, IEEE IEDM 2002. In the relevant document, a method of controlling the threshold value by alloying using two types of metal films other than the metal silicide is proposed. This method also uses diffusion by heat treatment and alloying reaction. However, the method of forming a microscopic gate electrode and forming the CMOS transistor is described as only “Lift-off” in “table 1”, and a specific method is not proposed, and thus is difficult to actually manufacture the CMOS device, and an effective method is not disclosed for the method of forming the dual gate when using metal for the gate material different from the case of the metal silicide.

[Prior Art 1] International Publication WO01/071807

[Prior Art 2] Japanese Laid-Open Patent Publication No. 2005-197753

Such threshold value controlling methods use materials having different work function with respect to silicon for the NMOS region and the PMOS region, and thus use thermal diffusion and alloying (silicide) reaction. In other words, the relevant method starts the reaction from the upper surface part of the gate electrode material and advances the reaction towards the lower part (direction of gate insulating film) to alloy (silicide) the entire gate electrode, thereby forming the alloy silicide of materials and compositions that differ between both conductivity type regions.

The reaction from the upper surface of the gate towards the lower part is drawn in frame format view in the figure (FIG. 1) shown in JaeHoon Lee et al. “Tunable Work Function Dual Metal Gate Technology for Bulk and Non-Bulk CMOS”, IEEE IEDM 2002, but actually, the alloying reaction advances with diffusion of metal elements advancing not anisotropically but isotropically according to the concentration gradient. In Japanese Laid-Open Patent Publication No. 2005-167251, the metal film and the silicon react through heat treatment and can be easily assumed that similar isotropic diffusion is occurring, but any description on the reaction at the region where the NMOS region and the PMOS region contact is not made nor considered.

In actual manufacturing, the reaction time (reaction calorie) adds excessive calorie (e.g., set longer by a few dozen % or more with respect to the minimum time required in silicide reaction) to the calorie at which all the gate electrodes react to ensure sufficient process margin with respect to the reaction.

Problems that arise in an example of forming the gate electrode by silicide reacting the polysilicon electrodes will be addressed below with reference to the method (FIGS. 2 to 5) of Japanese Laid-Open Patent Publication No. 2005-167251 describing a specific manufacturing process.

FIG. 29 is a plan view showing the PMIS region and the NMIS region of the silicon gate electrode in the CMIS transistor. FIG. 30 is a longitudinal cross sectional view taken along line P1-P2 of FIG. 29. FIG. 31 is a longitudinal cross sectional view taken along line P1-P2, showing the steps of how the silicide reaction advances. Different metal silicides are formed or metal silicides of the same metal but of different composition are formed in the NMIS region and the PMIS region when forming the gate electrode. In the former case, different metal silicides are formed by forming different metals. In the latter case, NiSi is formed in the NMIS region, and Ni3Si is formed in the PMIS region. Thus, the Ni film thickness is formed thicker in the PMIS region than in the NMIS region (see specifically, Japanese Laid-Open Patent Publication No. 2005-167251).

In both the former and the latter case, the atoms of the metal film (Ni film) do not diffuse anisotropically in the vertical direction but diffuse isotropically as shown with an arrow in FIG. 31, and thus the metal silicide mix with each other in the horizontal direction.

The minimum width of the isolation between the NMIS region and the PMIS region becomes more microscopic from 200 nm to 90 nm with miniaturization of the device. In the ion implantation step of forming the source/drain regions of the transistor, a film thickness that inhibits entering of ionic species to the channel under the gate electrode is required, and a dimension of about 80 nm to 150 nm is required for the height of the gate electrode. In the case of SRAM, in particular, the demand for miniaturization is strict, the PN isolation width is set narrow, and about the same extent of dimension is required for the gate height and the minimum PN isolation width.

As shown in FIG. 3 of F. Boeufet al. “0.248 μm2 and 0.334 μm2 Conventional Bulk 6T-SRAM bit-cells for 45 nm node Low Cost-General Purpose Applications”, VLSI Symposium 2005, the PN isolation interval is 95 nm, and the isolation width of about the same extent as the gate electrode height (about 85 nm) has been reported in the research stage of academic conference. The conventional metal silicide configuration is proposed in F. Boeuf et al. “0.248 μm2 and 0.334 μm2 Conventional Bulk 6T-SRAM bit-cells for 45 nm node Low Cost-General Purpose Applications”, VLSI Symposium 2005 to prioritize low cost.

In forming the gate electrode made of metal silicide, the amount of silicon corresponding to at least the gate electrode height and the silicon anticipating the process margin of manufacturing are converted to metal silicide.

In an ideal case, even when the boundary between the PMIS region and the NMIS region of the gate (hereinafter referred to as PN boundary) is positioned at the middle of the transistor isolation insulating film (hereinafter referred to as PN isolation) of PMIS and NMIS, the materials of the respective gate electrodes of the PMIS region and the NMIS region in the vicinity of the PN isolation diffuses with each other when the silicide reaction advances to not less than the distance of half the PN isolation width in the horizontal direction.

That is, in the vicinity of the PN isolation, the threshold voltage of the transistor fluctuates when deviated from the desired metal silicide material or composition and the work function changes, and the expected drain current may not be obtained. As a result, the normal operation of the semiconductor device cannot be obtained, and the yield lowers.

An example of forming the gate with metal silicide, and changing the composition thereof between the NMIS FET transistor and the PMIS FET transistor has been described above. In JaeHoon Lee et al. “Tunable Work Function Dual Metal Gate Technology for Bulk and Non-Bulk CMOS”, IEEE IEDM 2002, specific method of forming the gate electrode is not proposed, and a problem in that the transistor performance changes due to mutual diffusion similarly arises when using different metal alloys as in JaeHoon Lee et al. “Tunable Work Function Dual Metal Gate Technology for Bulk and Non-Bulk CMOS”, IEEE IEDM 2002 even if the gate electrode is formed using any method.

### SUMMARY OF THE INVENTION

It is an object of the present invention to provide, taking aforementioned problems into consideration, both when forming the dual gates with metal silicides different from each other and when forming the dual gates with metal and metal alloy, a method of preventing mutual diffusion of said metal film atoms (gate materials) in forming gate electrodes.

The main subject of the present invention relates to a semiconductor device including a CMIS transistor. In the present semiconductor device, the materials of the gate electrodes differ between the NMIS transistor and the PMIS transistor.

The gate electrodes of the NMIS transistor and the PMIS transistor are isolated from each other and face each other above the isolation insulating film positioned at a boundary of the NMIS region and the PMIS region.

Furthermore, the opposing surfaces of the gate electrodes are electrically connected to each other by a conductive film.

According to the main subject of the present invention, a problem in that the NMIS transistor and the PMIS transistor performance change due to mutual diffusion of gate materials at the PN boundary and further the lowering of the yield due to the abnormal operation can be prevented.

Additionally, according to the configuration disclosed in the main subject of the present invention, even when the heat produced through heat treatment in a later process (forming an inter-layer insulating film on the CMIS transistor and furthermore layouting metal wiring on the inter-layer insulating film) is conducted to both gate electrodes of the CMIS transistor, the metal mutual diffusion between the both gate electrodes can be also prevented.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 and 3 are plan views showing the manufacturing step of a semiconductor device according to a first embodiment of the present invention;

FIG. 2 is a longitudinal cross sectional view taken along line A1-A2 of FIG. 1;

FIG. 4 is a longitudinal cross sectional view taken along line A1-A2 of FIG. 3;

FIGS. 5 to 9 are longitudinal cross sectional view of showing the manufacturing step of the semiconductor device according to the first embodiment of the present invention;

FIG. 10 is a top view of the semiconductor device according to the first embodiment of the present invention;

FIGS. 11 and 13 are plan views of manufacturing step of a semiconductor device according to a second embodiment of the present invention;

FIG. 12 is a longitudinal cross sectional view taken along line B1-B2 of FIG. 11;

FIG. 14 is a longitudinal cross sectional view taken along line B1-B2 of FIG. 13;

FIGS. 15 and 16 are longitudinal cross sectional views of showing the manufacturing step of the semiconductor device according to the second embodiment of the present invention;

FIG. 17 is a plan view showing the manufacturing step of a semiconductor device according to a third embodiment of the present invention;

FIG. 18 is a plan view showing a configuration of an etching mask used in the third embodiment;

FIG. 19 is a plan view showing the manufacturing step of the semiconductor device according to the third embodiment;

FIG. 20 is a longitudinal cross sectional view taken along line C1-C2 of FIG. 19;

FIGS. 21 to 23 are longitudinal cross sectional views showing the manufacturing step of a semiconductor device according to a fourth embodiment;

FIGS. 24 to 26 are longitudinal cross sectional views showing the manufacturing step of a semiconductor device according to a fifth embodiment;

FIG. 27 is a view showing a circuit configuration of an SRAM;

FIG. 28 is a plan view showing a layout of an SRAM circuit in an SAM region of a semiconductor device according to a sixth embodiment;

FIGS. 29 to 31 are longitudinal cross sectional views showing the manufacturing step of a semiconductor device according to a related art and the problems thereof.

### DESCRIPTION OF THE PREFERRED EMBODIMENTS

### First Embodiment

The outline of the features of the present embodiment is as described below. That is, the gate electrodes are formed at the position above the isolation insulating film isolating the NMIS region and the PMIS region so that the gate electrode of the NMIS transistor and the gate electrode of the PMIS transistor are isolated/independent and face each other by way of a gap, and the gap sandwiched between the side surfaces of the gate electrodes is completely filled with insulating material, that is, a side wall spacer. The first and second metal films of different type or of the same type (but different film thickness) are then formed on the surface of each gate electrode, and thereafter, silicide reaction is promoted by heat treatment to form each gate electrode made of metal silicide of different type or of same type but different composition. In silicide reaction, the portion (insulating film) of the side wall spacer formed in the gap exerts a function of preventing diffusion, that is, mutual diffusion in the horizontal direction of the first and second metal film atoms. Subsequently, the gate electrodes are electrically connected to each other by a conductive film. The conductive film is embedded in a connection hole opened in an inter-layer insulating film formed on the gate electrodes, and functions as a so-called barrier metal in the subsequent steps. The present embodiment will be specifically described with reference to the drawings.

After forming a gate insulating film on a surface of a semiconductor substrate including a p-type well and an n-type well as well as an isolation insulating film, a gate electrode layer including polysilicon film is formed on the gate insulating film. At this stage, the portion of the NMIS transistor gate electrode and the portion of the PMIS transistor gate electrode are integrated in the gate electrode layer.

The gate electrode layer is then patterned through a combination of the lithography method and the etching method. Just them, formed is a pattern in which the gate electrodes face each other and are isolated by a constant gap (e.g., 50 nm to 100 nm: corresponding to a gap 10 to be hereinafter described) so that the gate electrode of the NMIS region and the gate electrode of the PMIS region do not connect to each other above the isolation insulating film (e.g., width 100 nm to 200 nm: correspond to isolation insulating film portion 5S to be hereinafter described) at the PN boundary.

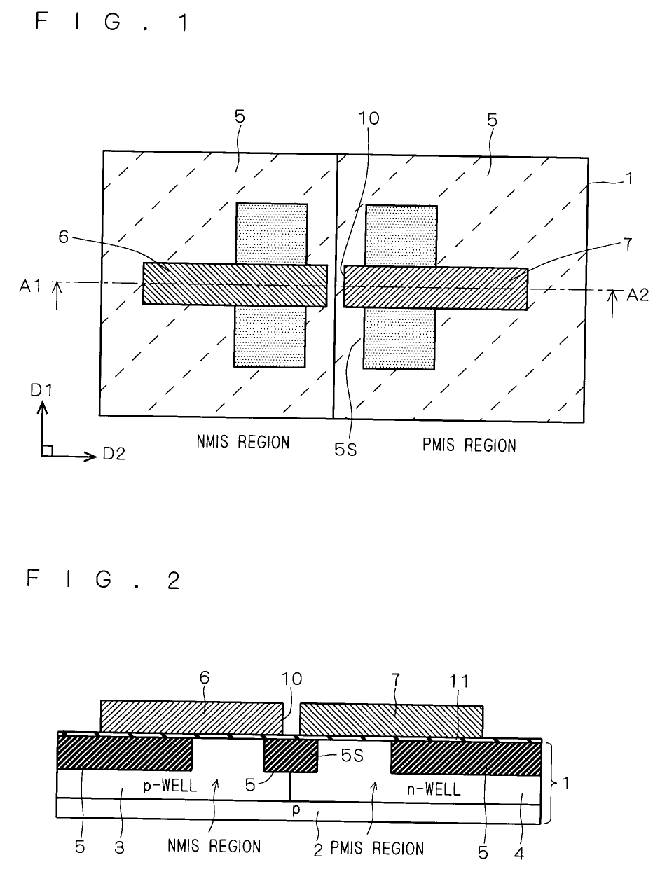

Subsequently, LDD region is formed on each of NMIS region and PMIS region with the gate electrode as a mask through a well-known method, that is, ion implantation method. FIG. 1 is a plan view of the semiconductor device including a CMIS configuration at the terminating stage of the above step. FIG. 2 is a longitudinal cross sectional view taken along line A1-A2 of FIG. 1.

As shown in FIGS. 1 and 2, a substrate 1 includes a p-well 3 and an n-well 4 formed on a p-type semiconductor layer 2, and also includes an isolation region 5. In particular, the portion formed at the boundary (PN boundary) between the NMIS region and the PMIS region out of the isolation region 5 is denoted with reference number 5S. The direction D1 indicated in FIG. 1 is the source-channel-drain direction (direction of gate length or channel length). Aspects to be noted at this stage is that the gate electrode 6 of the NMIS region and the gate electrode 7 of the PMIS region each extending in a gate width direction D2 orthogonal in plane with the source-channel-drain direction D1 are isolated and face each other by way of a gap or a void 10 extending in the source-channel-drain direction D1 above the isolation region 5S positioned at the PN boundary. Reference number 11 indicates the gate insulating film.

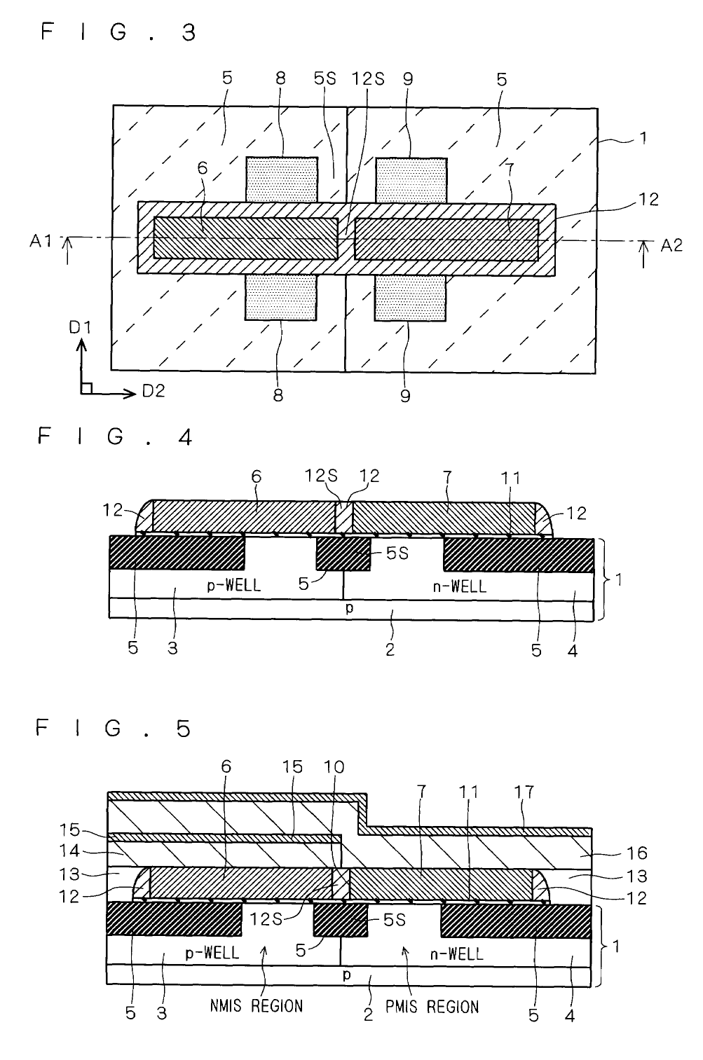

A side wall spacer 12 being an insulating film of silicon oxide or silicon nitride is formed on the entire side surface of both gate electrodes 6, 7 formed by silicon film. In this case, the other portion of the gate insulating film 11 except of a portion positioned immediately below both gate electrodes 6, 7, remains only at the lower part of the side wall spacer 12 through over etching, and the portion to be formed with the source/drain regions is removed. Alternatively, after the gate electrodes 6, 7 are patterned, etching is performed with the gate electrodes 6, 7 as the mask, so that the gate insulating film 11 remains only under the gate electrodes 6, 7. The gap 10 is entirely filled with the insulating film of the side wall spacer 12 when forming the side wall spacer 12 since the space between the gate electrodes 6, 7 of both conductivity type is narrow. However, the gap 10 does not need to be completely filled with the insulating film. The source/drain regions of high dose are formed in the NMIS region and the PMIS region through a well-known ion implantation method. FIG. 3 is a plan view showing the configuration of the semiconductor device manufactured as a result of the above steps, and FIG. 4 is a longitudinal cross sectional view taken along line A1-A2 of FIG. 3.

As shown in FIGS. 3 and 4, the side surfaces of each gate electrode 6, 7 are entirely covered by the insulating film of the side wall spacer 12. The gap 10 formed by the opposing surfaces of both gate electrodes 6, 7 is completely filled with the side wall spacer 12. In particular, the portion of the side wall spacer 12 that completely fills the gap 10 is denoted with reference number 12S, in FIGS. 3 and 4. The side wall spacer portion 12S exerts an important function (function of suppressing mutual diffusion of metal atoms) in the siliciding step of the gate electrodes to be hereinafter described. Furthermore, the NMIS region of the substrate 1 includes opposing source/drain regions 8 in the source-channel-drain direction D1 by way of a channel region immediately below the gate electrode 6, as shown in FIG. 3. Similarly, the PMIS region of the substrate 1 includes opposing source/drain regions 9 in the source-channel-drain direction D1 by way of a channel region immediately below the gate electrode 7.

The difference with the conventional manufacturing step is as follows. The NMIS transistor gate and the PMIS transistor gate are connected to each other in the SRAM pattern of FIG. 3 in F. Boeuf et al. “0.248 μm2 and 0.334 μm2 Conventional Bulk 6T-SRAM bit-cells for 45 nm node Low Cost-General Purpose Applications”, VLSI Symposium 2005, whereas the NMIS transistor gate electrode 6 and the PMIS transistor gate electrode 7 are patterned into a shape not connected to each other in the present embodiment. That is, the gate electrode of the NMIS transistor and the gate electrode of the PMIS transistor have a configuration isolated and independent from each other in terms of pattern.

Thereafter, the steps similar to the steps shown in FIGS. 2 to 4 of Japanese Laid-Open Patent Publication No. 2005-167251 are performed. That is, the insulating film (not shown) covering both gate electrodes 6, 7 and the side wall spacer 12 is formed, and the film thickness of the insulating film is reduced to form the insulating film 13 covering the entire side surface of the side wall spacer 12 excluding the side wall spacer portion 12S and the exposed surface of the substrate 1, as shown in FIG. 5, thereby exposing only the upper surface of the gate electrodes 6, 7 and the upper surface of the side wall spacer portion 12S. In addition, a first metal film 14 is entirely formed on the upper surface of the side wall spacer portion 12S, the upper surface of the gate electrodes 6, 7, and the upper surface of the insulating film 13, and furthermore, a metal film (diffusion preventing film) 15 of TiN for preventing diffusion of atoms of a second metal film 16 is entirely formed on the upper surface of the first metal film 14. Subsequently, the first metal film 14 and the metal film 15 of TiN are patterned to expose one part of the upper surface of the side wall spacer portion 12S in the PMIS region and the entire upper surface of the gate electrode 7. After patterning, the second metal film 16 is stacked and formed on the exposed surface of the metal film 15 of TiN on the NMIS side, the exposed side surface of the first metal film 14, the exposed one part of the upper surface of the side wall spacer portion 12S, the upper surface of the gate electrode 7, and the exposed upper surface of the insulating film 13 on the PMIS region side, and furthermore, a metal film 17 of TiN is entirely formed on the upper surface of the second metal film 16. The configuration shown in FIG. 5 is thereby achieved through such steps.

The process then proceeds to a heat treatment step of forming different metal silicides or metal silicides (e.g., NiSi and Ni3Si) of the same metal but having different composition in correspondence to the NMIS region and the PMIS region. The metal siliciding step by heat treatment is similar to the corresponding step disclosed in Japanese Laid-Open Patent Publication No. 2005-167251.

The composition of the metal silicide is adjusted by adjusting the film thickness ratio of the metal films to be formed with respect to the silicon film thickness of the base gate. For instance, the Ni film of 100 nm is formed as the first metal film 14, and the Ni film having a different film thickness of 300 nm is formed as the second metal film 16. Alternatively, the materials of both metal films 14, 16 are changed, for example, the Ni film of 100 nm is formed as the first metal film 14 and the Pt film of 100 nm is formed as the second metal film 16.

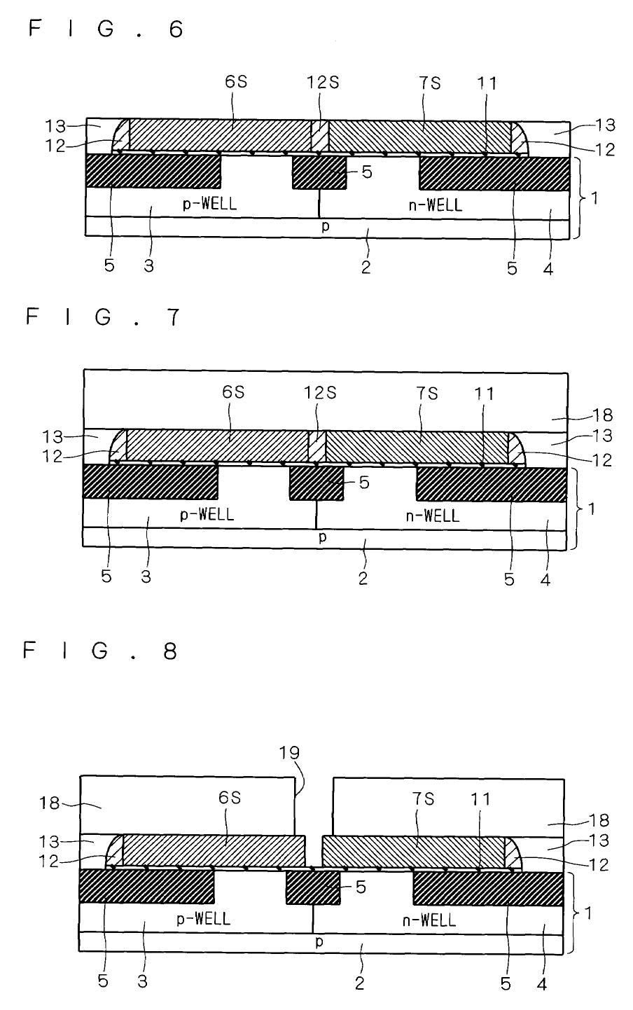

The gate electrodes 6, 7 become the metal silicide gate electrode 6S, 7S through the step of silicide reaction (see FIG. 6). The first and second metal films 14, 16 and the TiN films 15, 17 remaining as non-reactive part after the termination of the silicide reaction are removed from the main configuration. FIG. 6 is a longitudinal cross sectional view showing a configuration after the non-reactive part is removed. At this step, the gate electrodes 6, 7 of FIG. 5 become gate electrodes 6S, 7S made of metal silicide.

An inter-layer insulating film 18, for example, silicon oxide of 500 nm is formed on the upper surface of the respective metal silicide gate electrodes 6S, 7S, the upper surface of the side wall spacer portion 12S, and the upper surface of the insulating film 13 through CVD method, as illustrated in FIG. 7.

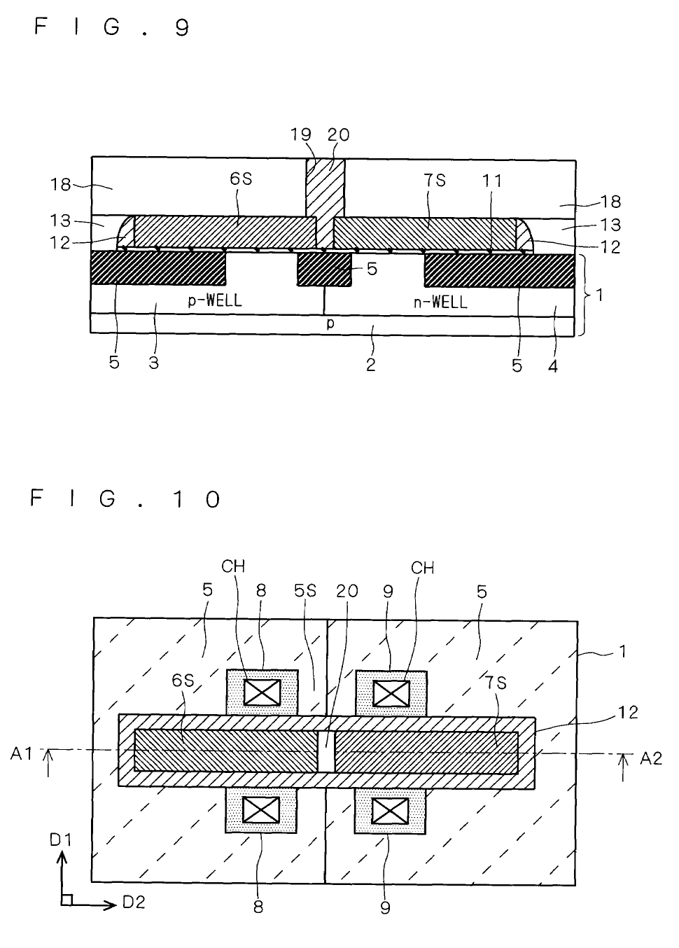

A connection hole 19 reaching to the upper surface of the gate insulating film 11 is formed in the inter-layer insulating film 18, as illustrated in FIG. 8, through a combination of lithography and etching techniques. The connection hole 19 must be at least formed until reaching the surface or the upper surface of the metal silicide gate electrodes 6S, 7S. Actually, the side wall spacer portion 12S formed at the boundary of the NMIS transistor gate 6S and the PMIS transistor gate 7S is also partially etched, as shown in FIG. 8, since the connection hole 19 is etched to the depth reaching not only to the gate of the SRAM transistor but also to the source/drain regions in an aim of supplying power to the metal wiring layer and the transistors. In particular, if the material (e.g., silicon oxide) of the side wall spacer 12 and the material of the inter-layer insulating film 18 are the same material, all the side wall spacer portion 12S completely filling the gap 10 is removed. If the material (e.g., silicon nitride) of the side wall spacer 12 differs from the material (e.g., silicon oxide) of the inter-layer insulating film 18, a selection ratio exists between the silicon nitride and the silicon oxide in this case, and thus only one part of the side wall spacer portion 12S is etched if the etching rate of the silicon nitride is low.

A conductive film 20 is then filled into the connection hole 19, as shown in FIG. 9. In this step, the conventional tungsten plug method is used. That is, the stacked configuration of Ti and TiN is formed as a barrier metal through CVD method, and thereafter, tungsten is formed through CVD method to completely fill the connection hole 19. Subsequently, the tungsten and the barrier metal other than of the connection hole 19 are removed through CMP method or etch back method, so that the barrier metal and the tungsten constituting the conductive film 20 are filled only in the connection hole 19. The metal film to be filled into the connection hole 19 as the conducive film 20 may be other than tungsten such as aluminum or copper, or may be TiN film.

FIG. 10 is a top view of a configuration shown in the longitudinal cross sectional view of FIG. 9. In other words, FIG. 9 is the longitudinal cross sectional view taken along line A1-A2 of FIG. 10. For the sake of convenience of the explanation, the contact hole 19 of FIG. 9 is not illustrated in FIG. 10. In FIG. 10, reference symbol CH denotes the contact hole in the source/drain regions 8, 9 in frame format. As shown in FIG. 10, the opposing surfaces in the D2 direction of the gates 6S, 7S are electrically connected to each other by the conductive film 20 at the PN boundary. In FIG. 10, the conductive film 20 is formed across the entire opposing surfaces of the gates 6S, 7S in the D1 direction, but the conductive film 20 may be formed over one part of the opposing surfaces of the gates 6S, 7S.

The subsequent steps lead to the conductive wiring step as per usual.

### Effect of First Embodiment

In the present embodiment, the pattern of the gate electrodes is assumed to have an independent shape for the NMIS region and the PMIS region, and the connection between the gates at the PN boundary is realized with the conducive film 20 to be filled into the connection hole 19 formed in the inter-layer insulating film 18. Therefore, according to the present embodiment, the above described configuration is realized by simply changing the mask pattern with respect to the conventional manufacturing step, and the mutual diffusion of the gate materials of the NMIS transistor and the PMIS transistor at the PN region is prevented without involving increase in manufacturing cost, and degradation of the performance of the CMIS transistor is prevented.

### Second Embodiment

The method of forming the metal silicide gate that can prevent mutual diffusion of the metal atoms to the gate of different conductivity-type in the silicide reaction of the gates in the CMIS transistor has been described in the first embodiment, but the technical means described in the first embodiment is also applicable to the metal film gate. Such application examples and variants are the features of the present embodiment.

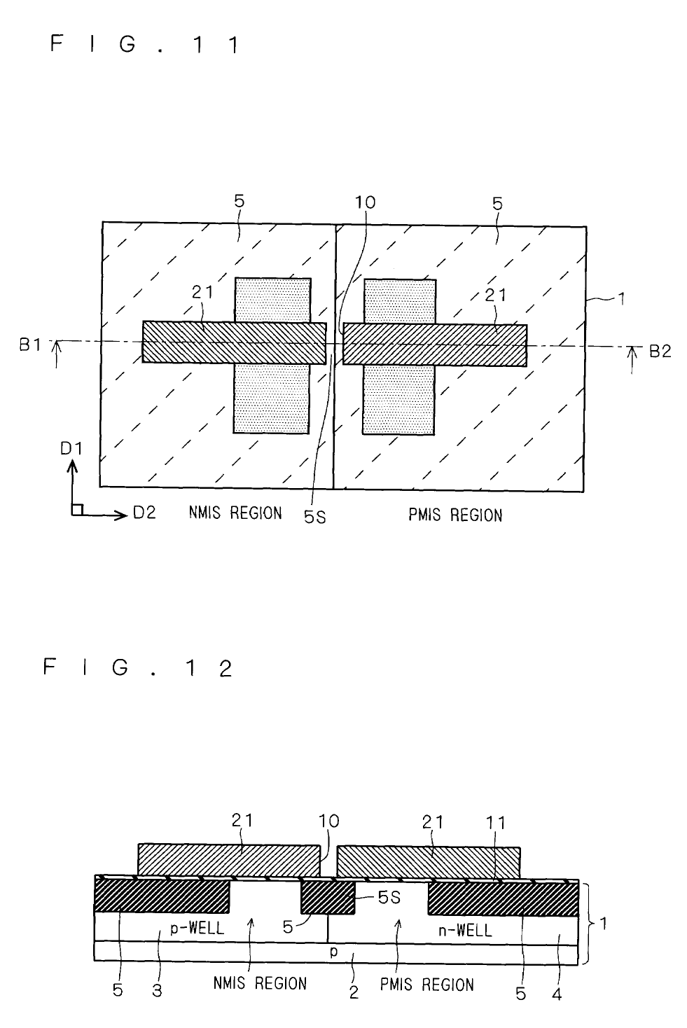

FIGS. 11 and 12, which are figures of the present embodiment, each corresponds to FIGS. 1 and 2 of the first embodiment. Therefore, identical reference characters are denoted for the corresponding components. However, a third metal film (e.g., Ta film) is formed in the present embodiment as each gate electrode 21 of the NMIS transistor and the PMIS transistor in place of the gate electrodes 6, 7 formed from silicon film. It is to be noted that, similar to the first embodiment, the NMIS region gate electrode 21 and the PMIS gate electrode 21 having an isolated and independent pattern face each other by way of the gap 10 in the gate width direction D2 at a position above the isolation insulating film 5S at the PN boundary.

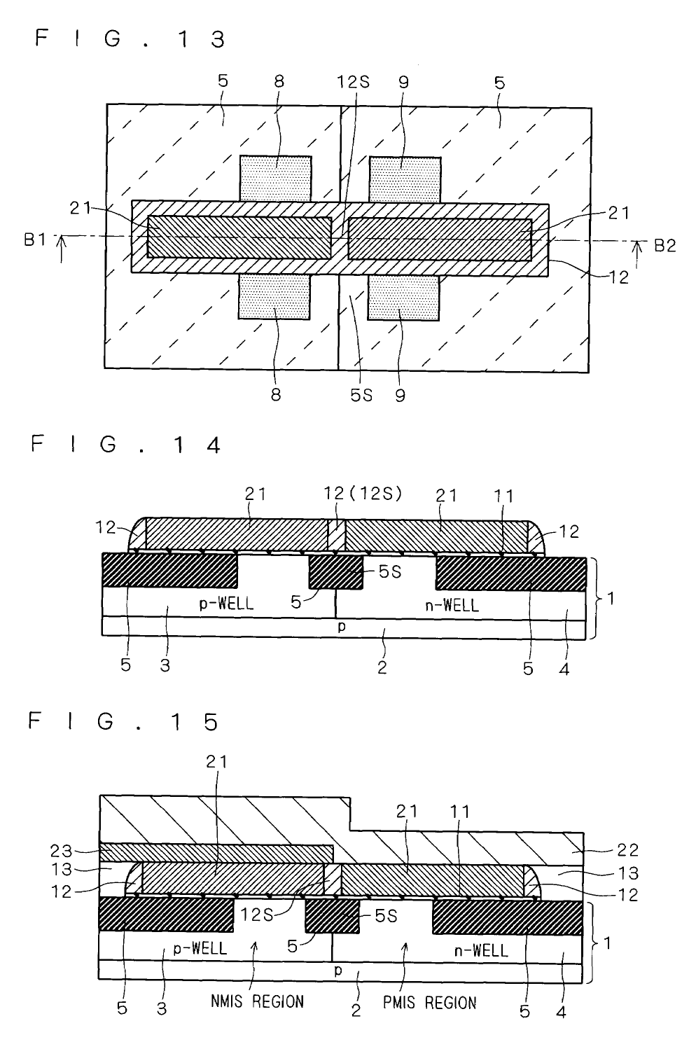

Furthermore, FIGS. 13 and 14 of the present embodiment correspond to FIGS. 3 and 4 of the first embodiment. Therefore, the insulating film of the side wall spacer 12 that entirely fills the gap 10 is also formed in the present embodiment. In particular, the insulating film out of the side wall spacer 12 that fills the gap 10 is denoted as the side wall spacer portion 12S, similar to the first embodiment.

Thereafter, the insulating film (not shown) for covering the both gate electrodes 21, 21 and the entire side wall spacer 12S is formed, similar to the first embodiment, and the film thickness of the insulating film is reduced to form the insulating film 13 shown in FIG. 15, so that the upper surface of each of the gate electrodes 21, 21 and the upper surface of the side wall spacer portion 12S are entirely exposed.

The longitudinal cross sectional view of FIG. 15 corresponds to FIG. 5 in the first embodiment, but in the present embodiment, only the TiN film (diffusion preventing film) 23 for preventing diffusion of metal atoms constituting a fourth metal film 22 is formed in the region (NMIS region in the example of FIG. 15) of one conductivity type through a combination of lithography and etching techniques, and thereafter, the fourth metal film (e.g., Ru film) 22 is formed on the upper surface of the third metal film 21, and the upper surface of the insulating film 13 in the exposed region of the other conductivity type (PMIS region in the example of FIG. 15), and the upper surface of the TiN film 23 on the former conductivity-type region side. The fourth metal film (Ru film) 22 and the third metal film (Ta film) 21 are then mixed through thermal diffusion method. In this case, since one conductivity type region (NMIS region in the example of FIG. 15) is covered by TiN film 23, the mutual diffusion of the third metal film 21 and the fourth metal film 22 are suppressed, and the metal atoms of the metal films 21, 22 do not mix in the relevant region. Furthermore, since the gates of the NMIS transistor and the PMIS transistor are isolated by interposing the side wall spacer portion 12S, mutual diffusion of metal atoms between the gates also do not occur.

Hereinafter, the remaining non-reactive fourth metal film 22 and the TiN film 23 serving as the diffusion preventing film in FIG. 15 are removed. The unnecessary metal film can be removed by a mixed solution of sulfuric acid and hydrogen peroxide solution and the like using the difference in resistance to acid chemicals between the metal silicide film and the non-reactive metal in the first embodiment, but drug solution cannot be used in the present embodiment since metal films 21, 22 are used. No method has been proposed in JaeHoon Lee et al. “Tunable Work Function Dual Metal Gate Technology for Bulk and Non-Bulk CMOS”, IEEE IEDM 2002 and in Japanese Laid-Open Patent Publication No. 2005-167251 regarding this aspect.

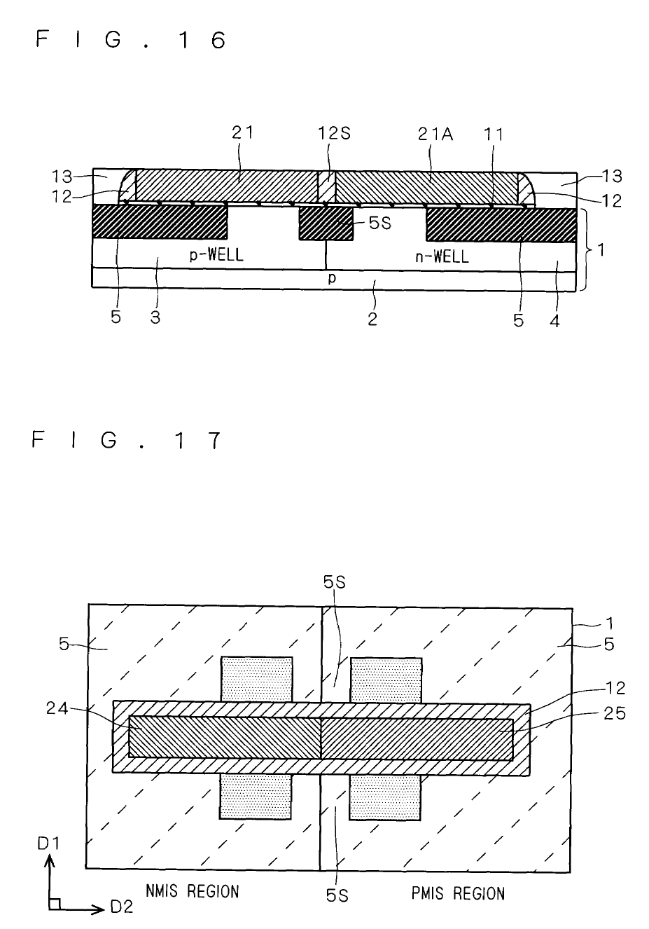

In the present embodiment, the non-reactive metal film is polished and flattened using the CMP method to remove the unnecessary fourth metal film 22 and the TiN film 23 of the diffusion preventing film protruding to the upper part from the upper surface of the gate electrodes. FIG. 16 is a longitudinal cross sectional view showing the configuration after the unnecessary fourth metal film 22 and the TiN film 23 are removed. As shown in FIG. 16, the gate electrode 21 of the NMIS region is structured by metal material containing Ta, whereas the gate electrode 21A in the PMIS region is structured by metal alloy film of Ta and Ru.

Hereinafter, the flow of the step of forming the inter-layer insulating film, step of forming connection hole, step of filling the conductive film, and the step of forming wiring is the same as the first embodiment, and thus the description of such steps will not be given.

The third metal film 21 and the fourth metal film 22 are not limited to the combination of Ta and Ru.

### Effect of Second Embodiment

Since the metal film having a lower resistance than the metal silicide is used, and different metal materials are used for the gate electrodes in different conductivity-type transistors, the mutual diffusion of metal atoms between the gate electrodes is further prevented.

### Third Embodiment

As the isolation width becomes narrower with miniaturization, setting the interval between the gate electrodes facing each other narrow in accordance with the isolation width becomes difficult in terms of limitation of lithography in the case of forming the aforementioned gap 10 (see FIG. 2) between the gate electrodes of the NMIS transistor and the PMIS transistor. The projecting amount from the active layer of the gate electrode to the isolation insulating film normally requires about 30 nm to 50 nm from the demands of lithography in order to ensure a gate length. The value combining the projection amount from both gate electrodes is 60 nm to 100 nm. As the width of the isolation insulating film at the boundary (PN boundary) between the NMIS region and PMIS region becomes narrow, the gap width between the gate electrodes must be narrowed (formed to not more than 50 nm), and lithography become more difficult.

The present embodiment thus proposes a method of forming a gap between narrow gate electrodes.

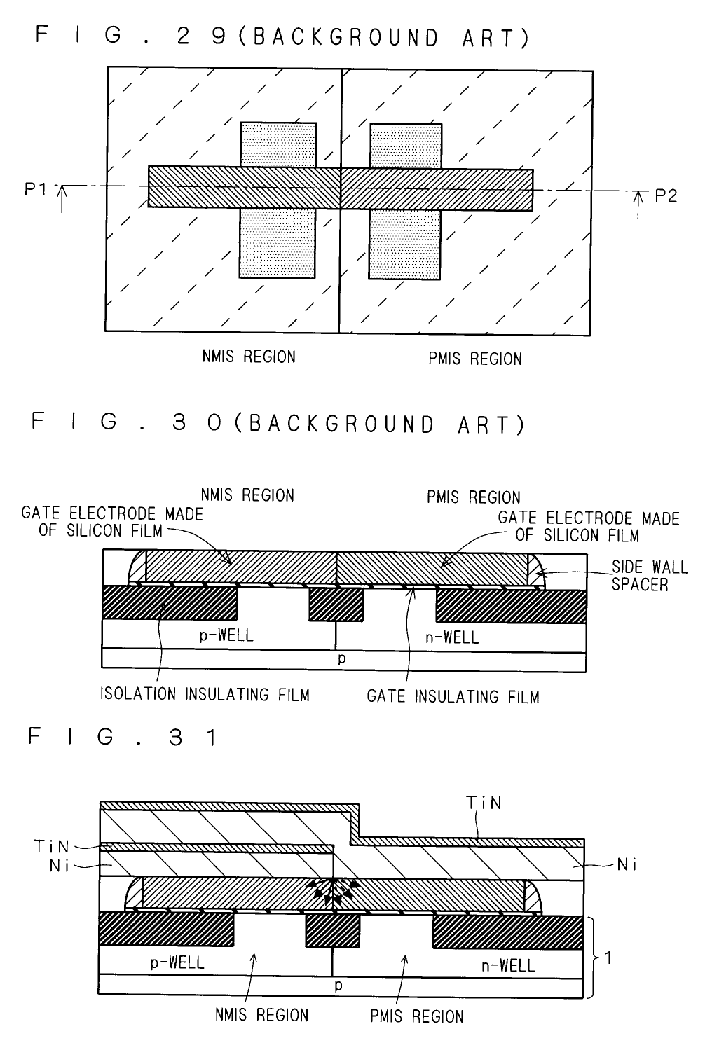

As in the step of FIG. 29, which is the view showing the problems of a related art, both gate electrodes 24, 25 each made of polysilicon film are formed on the substrate 1 so as to be connected to each other at the PN boundary without being isolated above the isolation insulating film 5S (see FIG. 2) at the PN boundary. After the step of FIG. 29 is completed, the side wall spacer 12 is formed on the entire side surface of the connected gate electrodes 24, 25 as in the related art. The configuration of the semiconductor device after the side wall spacer 12 is formed is shown in FIG. 17 which is a top view.

The insulating film (not shown) for entirely covering the gate electrodes 24, 25 and the side wall spacer 12 is subsequently formed. The insulating film 13 shown in FIG. 20 is then formed by reducing the film thickness of the insulating film, thereby exposing the entire upper surfaces of the gate electrodes 24, 25 connected at the PN boundary.

The etching mask 26 is then formed by photoresist. As shown in FIG. 18, the etching mask 26 has an opening for exposing only the gate electrodes 24, 25 at the PN boundary. In FIG. 18, one part of the side wall spacer 12 and the isolation insulating film 5S at the PN boundary are shown for the sake of convenience of illustration, but such portions 12, 5S are actually covered by the insulating film 13, and cannot be seen from above. Only the upper surfaces of the gate electrodes 24, 25 that are to be etched at the PN boundary are actually seen from the opening.

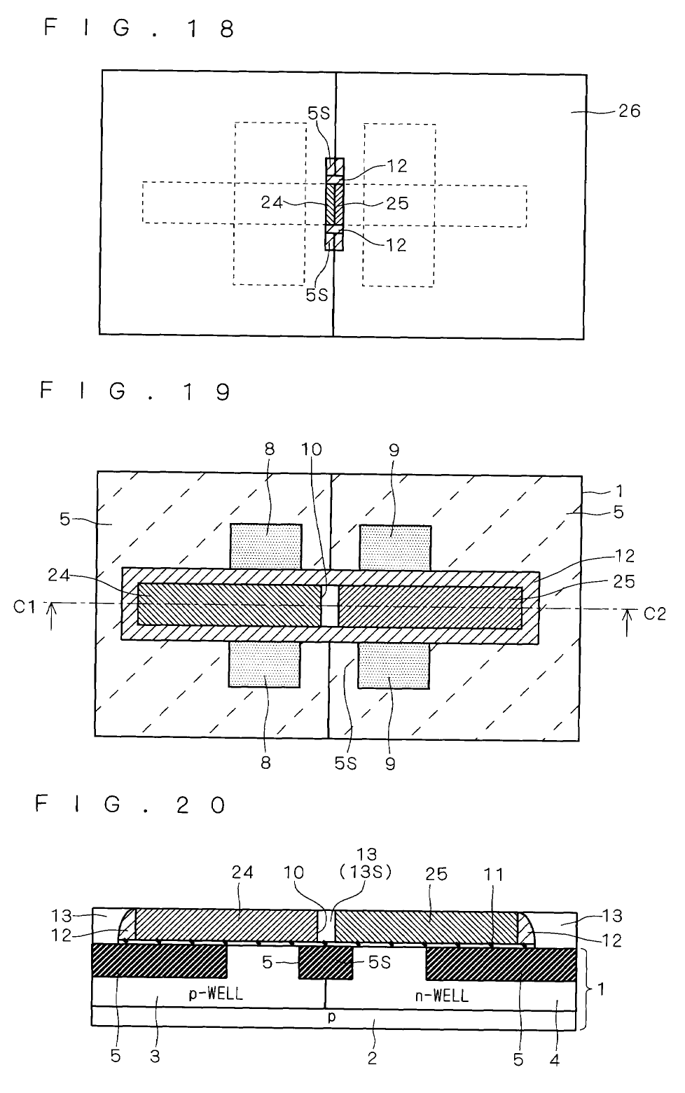

Only the portion of the gate electrodes (silicon film) 24, 25 at the PN boundary are etched through etching method using the etching mask 26, and thereafter, the etching mask 26 is removed (FIG. 19). According to such step, the gate electrodes 24, 25 are isolated from each other at the PN boundary, and the gap 10 is formed between the opposing surfaces of the gate electrodes 24, 25.

Subsequently, an insulating film (not shown) for covering both gate electrodes 24, 25 and the upper surface of the insulating film 13 is formed, and the insulating film is polished through the CMP method to expose the upper surfaces of the gate electrodes 24, 25 isolated from each other by way of the gap 10. At this time, as shown in FIG. 20, the gap 10 formed at the PN boundary by the above etching is filled with the insulating film 13S. The height of the upper surface of the insulating film 13S is almost the identical as the height of the upper surfaces of the gate electrodes 24, 25.

A device including a CMIS transistor comprising different metal silicide gate electrodes at the NMIS region and the PMIS region is completed through the steps (FIGS. 5 to 9) after FIG. 5 described above.

Obviously, a device including a CMIS transistor comprising a metal gate electrode and a metal alloy gate electrode isolated and facing each other at the PN boundary can be manufactured by applying the technical concept of the second embodiment described above to the present embodiment.

### Effect of Third Embodiment

According to the present embodiment, the pattern of the narrow gap 10 can be formed by facing the gate electrodes 24, 25 of both conductivity types at the PN boundary even if the width of the isolation insulating film located at the PN boundary is narrowed by miniaturization, and further miniaturization of the device can be achieved.

### Fourth Embodiment

The conductive film for connecting the both gate electrodes, which is the core of the present embodiment, has a configuration of being embedded and formed in an insulating film surrounding the both gate electrodes and having the upper surface located in the same plane as the upper surfaces of the both gate electrodes, where the upper end of the conductive film and the upper ends of the both gate electrodes are substantially in plane. According to such configuration, a connection hole does not need to be formed in the inter-layer insulating film formed in the CMIS transistor, and layout restriction of the wiring on the inter-layer insulating film due to additional formation of the connection hole is eliminated.

In each of first, second, and third embodiments described above, the conductive film 20 is formed in the connection hole 19 of the inter-layer insulating film 18 on the transistor to electrically connect the gate electrodes facing each other at the PN boundary (see FIGS. 8 and 9). In this case, the connection holes increase in terms of pattern, and the wiring cannot be formed just above the connection hole 19 in terms of layout. That is, the layout restriction is required in that the pattern wiring must be formed so that the wiring layer to be formed on the inter-layer insulating film 18 at the post-step after FIGS. 9 and 10 does not contact the conductive film 20 filled in the connection hole 19. In the present embodiment, a manufacturing method and a semiconductor configuration for eliminating the layout restriction of the pattern wiring are proposed.

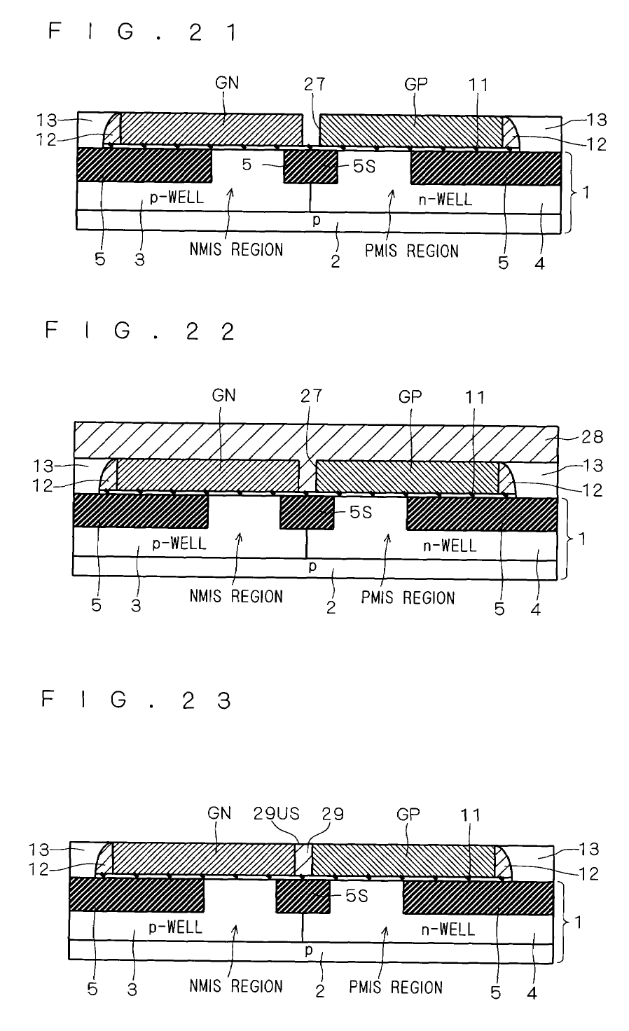

First, after the step of FIG. 6 in the first embodiment or after the step of FIG. 16 in the second embodiment, or after the step of FIG. 20 in the third embodiment, that is, after forming the gate electrodes GN, GP of the NMIS region and the PMIS region made of inhomogeneous metal silicide film or from metal film and alloy film, the etching mask is formed on the gate electrodes GN, GP through photoresist and the like, the side wall spacer portion 12S (first and second embodiments) or the insulating film portion 13S (third embodiment) at the PN boundary is removed through etching method, and the etching mask is further removed to form an opening 27 at the PN boundary, as shown in FIG. 21.

Subsequently, the conductive film (combination of barrier metal made of stacked configuration of Ti and TiN, and tungsten) 28 is formed on both gate electrodes GN, GP and on the insulating film 13 through CVD method to fill the opening 27 with conductive film 28, as shown in FIG. 22.

The conductive film 28 is then scraped from the upper part through CMP method or etch back method, so that the conductive film 29 remains only in the opening 27 of the PN boundary, as shown in FIG. 23. Therefore, the upper surface 29US of the conductive film 29 has almost the identical height as the upper surfaces of the gate electrodes GN, GP. In other words, the conductive film 29 does not contact the upper surfaces of the gate electrodes GN, GP. Furthermore, the opposing surfaces (side surfaces) of the gate electrodes GN, GP facing each other at the PN boundary are electrically conducted to each other by the contact with the conductive film 29.

The inter-layer insulating film (not shown) is then formed on the both gate electrodes GN, GP and the insulating film 13, and the device is completed with the conventional manufacturing method. In this case, the presence of the conductive film 29 does not become a hindrance in the formation of the wiring layer in terms of layout. Therefore, the wiring layer can be laid above the conductive film 29.

### Effect of Fourth Embodiment

According to the present embodiment, the number of manufacturing steps increases, but the conductive film 29 is formed at the PN boundary without forming the connection hole in the inter-layer insulating film, and the gate electrodes GN, GP made of different materials can be electrically contacted to each other. Thus, the layout restriction of the wiring layer is eliminated.

### Fifth Embodiment

The present embodiment proposes a method of using the conventional pattern without requiring the connection of the side surfaces of the gates of the NMIS transistor and the PMIS transistor isolated and facing each other by the conductive film at the PN boundary, as in the first to fourth embodiments described above.

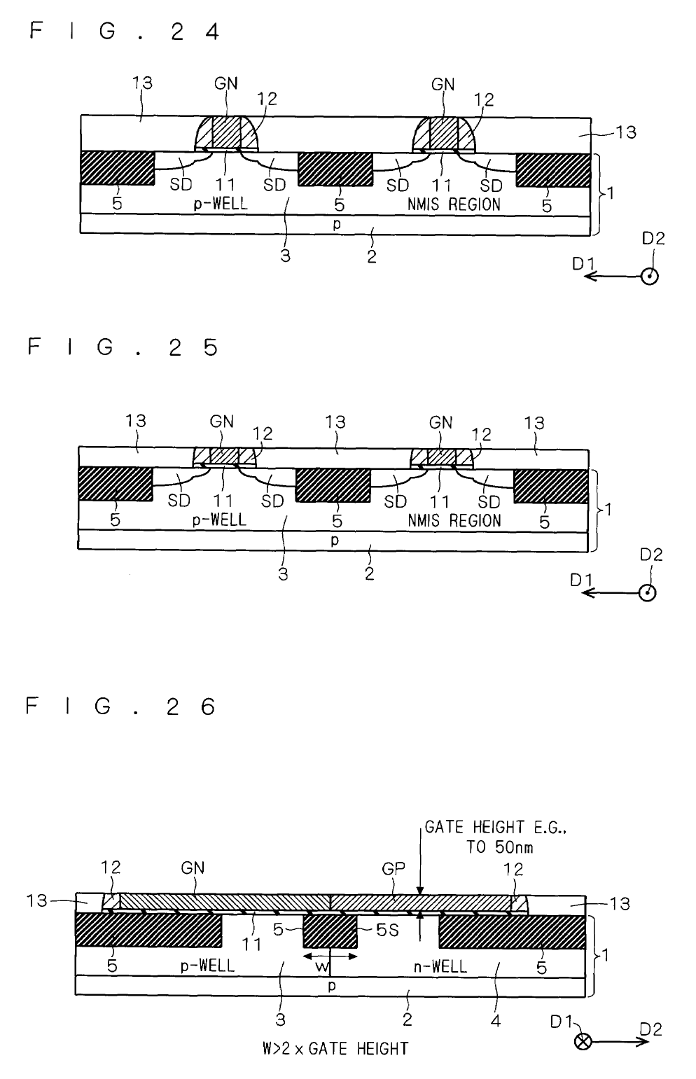

The gate electrode functions as an ion implantation mask to form the source/drain regions, and thus the source/drain regions are formed similar to the conventional manufacturing step, and the configuration shown in FIG. 24 showing the longitudinal cross sectional view in the source-channel-drain direction D1 is obtained. In FIG. 24, reference character SD denotes the source/drain region. After the configuration of FIG. 24 is formed, the film thickness of the gate electrode GN (GP) is reduced. Here, the film thickness of the gate electrode is set so that the mutual diffusion length of the gate materials of the NMIS transistor and the PMIS transistor in siliciding or alloying is shorter than the width W of the PN isolation insulating film 5S. For instance, the film thickness of the gate electrode GN (GP) is less than half the width W of the PN isolation insulating film 5S. In the example, the height of the gate electrode is 45 nm when the width W of the PN isolation insulating film 5S is 100 nm.

In the step shown in FIG. 25, one method of reducing the film thickness of the gate electrode GN (GP) is to polish the insulating film 13 and the silicon film of the gate electrode GN(GP) through CMP method.

Alternatively, in the step shown in FIG. 25, the film thickness of the gate electrodes GN(GP) may be reduced by etching the insulating film 13 and the polysilicon of the gate electrode GN(GP) through dry etching method. In this case, both the insulating film 13 and the gate electrodes GN(GP) may be simultaneously etched, but the polysilicon may be etched first to reduce the film thickness of the gate electrode GN(GP), and thereafter, the insulating film 13 may be etched to reduce the film thickness thereof, thereby aligning the height of the gate electrode and the height of the insulating film.

Alternatively, the insulating film 13 may be polished through CMP method to reduce the film thickness thereof after etching the gate electrode GN(GP) of polysilicon through dry etching method, thereby aligning the height of the gate electrode and the height of the insulating film.

Only the gate electrode GN(GP) may be etched, and the height thereof may be made to less than half the width W of the isolation insulating film 5S at the PN boundary.

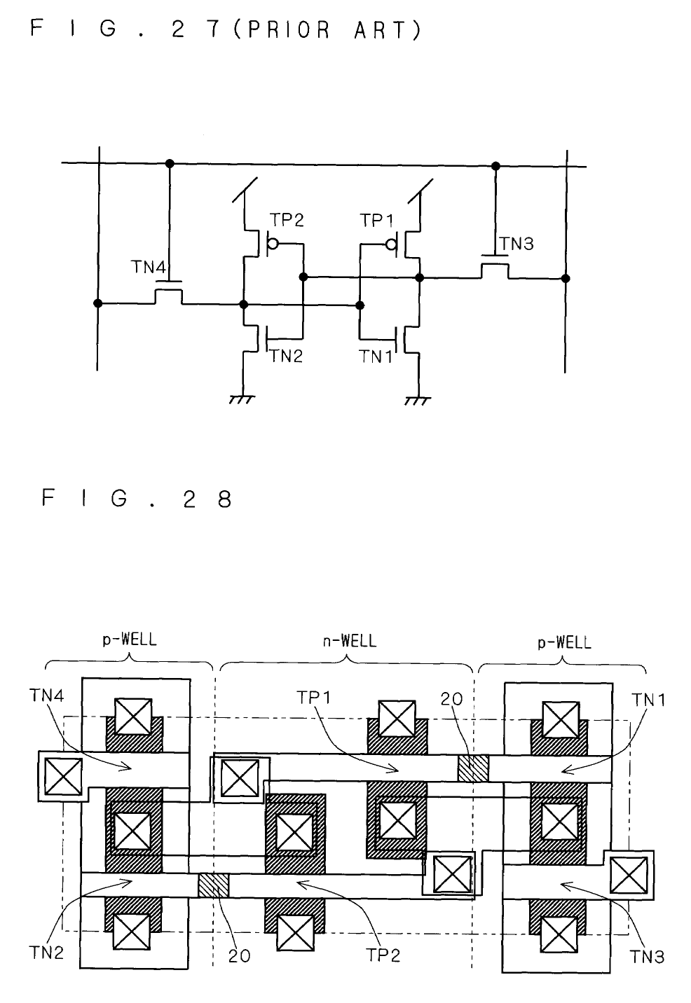

FIG. 25 is a longitudinal cross sectional view in the source-channel-drain direction D1 of the gate, and FIG. 26 is a longitudinal cross sectional view in the direction D2 connecting the PMIS region and the NMIS region.

Hereinafter, the device is completed through processes (siliciding step) of FIGS. 2 to 5 in Japanese Laid-Open Patent Publication No. 2005-167251 as described in the first embodiment. Subsequently, the inter-layer insulating film is formed on the gate electrodes, and the wiring layer is arranged thereon.

The case of using polysilicon as the gate electrode material has been described, but metal film, alloy film of Ta and Ru, and other materials may be used for the gate electrode. In this case, the process of forming the diffusion preventing film 23 in the region that is not alloyed is selected as shown in FIG. 15 for the subsequent processes.

A method of separately etching or polishing the gate electrodes and the insulating film is adopted as a method of reducing the film thickness of the gate electrode when using the metal film, and which can respond to manufacturing various gate electrode materials, thereby increasing the degree of freedom in the selection of the gate material.

The step of the present embodiment can be summarized as below. The present embodiment includes a step of patterning the material films (polysilicon film, metal film, and the like) to become the gate electrodes of the first conductivity type MIS transistor and the second conductivity type MIS transistor to a shape of connecting to each other above the isolation insulating film positioned at the boundary of the first conductivity type MIS region and the second conductivity MIS region; a step of forming the source/drain region in each conductivity type MIS region through ion implantation with the gate electrodes as the mask; a step of forming the insulating film for covering both gate electrodes; a step of exposing the upper surfaces of both gate electrodes by reducing the film thickness of the insulating film; a step of reducing the film thickness of both gate electrodes so that the diffusion length of the gate electrode material of both conductivity type becomes less than the width of the isolation insulating film positioned at the boundary; and a step of forming the gate electrodes made of different materials through heat treatment.

### Effect of Fifth Embodiment

According to the present embodiment, the mutual diffusion length is short, the mutual diffusion region is shorter than half the width W of the PN isolation insulating film, and the performance of the transistors of both conductivity type does not degrade even if the film thickness of the gate electrode is formed thin, and the NMIS transistor and the PMIS transistor form different materials as the gate electrodes through thermal diffusion and reaction.

### Sixth Embodiment

In the semiconductor device in which an SRAM region and a logic circuit region coexist, in general, demand for miniaturization is strict and the width of the PN isolation insulating film is narrow in the SRAM region, but the SRAM region is a cluster of the same memory cells and is configured from a specific circuit pattern. In the logic circuit region, on the other hand, the width of the PN isolation insulating film can be set wider than the SRAM region, but the degree of freedom of pattern layout becomes essential in designing the pattern in correspondence to various logic circuits that complies the request of the customer.

The electrical connection of both conductivity type gate electrodes by means of the connection hole (contact hole) 19 shown in the first embodiment is used in the SRAM region, and the width W of the PN isolation insulating film is set to a value larger than twice the height (film thickness) of the gate electrode in the logic circuit region using the method described in the fifth embodiment.

FIG. 27 is a well-known circuit diagram showing the configuration of the SRAM. In FIG. 27, NMIS transistors TN1, TN2 are drive transistors of the SRAM circuit, PMIS transistors TP1, TP2 are load transistors of the SRAM circuit, and NMIS transistors TN3, TN4 are access transistors of the SRAM circuit. Furthermore, FIG. 28 is a top view showing the layout (wiring configuration) of one SRAM circuit (FIG. 27) in the SRAM region. In FIG. 28, the side wall spacer 12 is not given for the sake of convenience of illustration. As shown in FIG. 28, the gates of the transistors TN1, TP1 are electrically connected to each other by the conductive film 20 and similarly, the gates of the transistors TN2, TP2 are electrically connected to each other by the conductive film 20 at the PN boundary as shown in FIG. 10 in the SRAM region according to the present embodiment.

### Effect of Sixth Embodiment

According to the present embodiment, the mutual diffusion of the gate electrode materials is prevented and degradation of the transistor performance is prevented without limiting the degree of freedom of circuit design.

### (Variant)

The metal silicide gate electrodes are formed through the reaction between metal and silicon gate pattern when forming the gate electrodes with silicide in the embodiment described above, but germanium may be contained in silicon.

The substrate may be an SOI substrate in addition to the normal bulk silicon substrate. The substrate may be a compound semiconductor substrate. The channel region may be polysilicon and the substrate may be a polysilicon TFT.

The gate insulating film is not limited to silicon oxide or silicon nitride, and may be insulating film of high dielectric constant such as hafnium oxide.

### (Reference)

The embodiments of the present invention have been disclosed and described in detail above, but the above description merely illustrates applicable forms of the present invention, and should not be construed as limiting the present invention. That is, various modifications and variants on the described aspects can be construed within the range not deviating from the scope of the invention.

The present invention is suited to application on a semiconductor device including a CMIS transistor in which the gate electrode material differs between the NMIS region and the PMIS region, and the gate material is metal silicide, metal, or alloy.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising a CMIS transistor; wherein
materials of gate electrodes differ between an NMIS transistor and a PMIS transistor;
the gate electrodes of said NMIS transistor and said PMIS transistor are isolated from each other and face each other above an isolation insulating film positioned at a boundary of an NMIS region and a PMIS region; and
opposing surfaces of the gate electrodes are electrically connected to each other by a conductive film.

2. The semiconductor device according to claim 1, wherein
the materials of said gate electrodes are selected from metal silicide, metal, and metal alloy.

3. The semiconductor device according to claim 2, wherein
the gate electrode of said NMIS transistor and the gate electrode of said PMIS transistor are both made of nickel silicide, and composition ratio of Ni/Si differ between said NMIS transistor and said PMIS transistor.

4. The semiconductor device according to claim 1, wherein
said conductive film connecting said gate electrodes to each other is embedded in a connection hole located in an inter-layer insulating film covering said gate electrodes and reaching to at least the upper surfaces of the gate electrodes.

5. The semiconductor device according to claim 1, wherein
a gap sandwiched between said opposing surfaces of said gate electrodes above said isolation insulating film positioned on said boundary is filled with said conductive film; and
the height of said conductivity film is almost the identical as the height of said gate electrodes.

6. A semiconductor device comprising a CMIS transistor; wherein
materials of gate electrodes differ between an NMIS transistor and a PMIS transistor;
the gate electrodes of said NMIS transistor and said PMIS transistor are connected to each other above an isolation insulating film positioned at a boundary of an NMIS region and a PMIS region; and
the height of said gate electrodes is less than half the width of said isolation insulating film.

7. A semiconductor device in which an SRAM region and a logic circuit region coexist, said semiconductor device comprising a CMIS transistor in which materials of gate electrodes differ between an NMIS transistor and a PMIS transistor at each of said SRAM region and said logic circuit region; wherein
in each CMIS transistor of said SRAM region,
the gate electrodes of said NMIS transistor and said PMIS transistor are isolated from each other and face each other above an isolation insulating film positioned at a boundary of an NMIS region and a PMIS region,
opposing surfaces of said gate electrodes are electrically connected by a conductive film to each other, and
said conductive film is embedded in a connection hole located in an inter-layer insulating film covering said gate electrodes and reaching to at least the upper surfaces of the gate electrodes; and
in each CMIS transistor of said logic circuit region,
the gate electrodes of said NMIS transistor and said PMIS transistor are connected to each other above an isolation insulating film positioned at a boundary of an NMIS region and a PMIS region; and
the height of said gate electrodes is less than half the width of said isolation insulating film.

8. A method of manufacturing a semiconductor device comprising a CMIS transistor, the method comprising the steps of:
patterning a silicon film to become each gate electrode of a first conductivity-type MIS transistor and a second conductivity-type MIS transistor to a shape isolated without connecting to each other and facing each other above an isolation insulating film positioned at a boundary of the first conductivity-type MIS region and the second conductivity-type MIS region;
forming a side wall spacer made of an insulating film for completely filling a gap between the gate electrodes and for entirely covering the side surfaces of said gate electrodes;
forming an insulating film for covering said gate electrodes and said side wall spacer;
exposing the upper surfaces of said gate electrodes including the opposing surfaces connected to each other with a side wall spacer portion filling said gap by reducing the film thickness of said insulating film;
forming a first metal film and a second film on the upper surface of the gate electrode of said first conductivity-type MIS region and the upper surface of the gate electrode of said second conductivity-type MIS region, respectively;
forming a gate electrode of first metal silicide and a gate electrode of second metal silicide in said first conductivity-type MIS region and said second conductivity-type MIS region, respectively, through heat treatment; and
removing the non-reactive first metal film and the second metal film.

9. A method of manufacturing a semiconductor device comprising a CMIS transistor, the method comprising the steps of:
patterning a third metal film to become each gate electrode of a first conductivity-type MIS transistor and a second conductivity-type MIS transistor to a shape isolated without connecting to each other and facing each other above an isolation insulating film positioned at a boundary of the first conductivity-type MIS region and the second conductivity-type MIS region;
forming a side wall spacer made of an insulating film for completely filling a gap between the gate electrodes and for entirely covering the side surfaces of said gate electrodes;
forming an insulating film for covering said gate electrodes and said side wall spacer;
exposing the upper surfaces of said gate electrodes including the opposing surfaces connected to each other with a side wall spacer portion filling said gap by reducing the film thickness of said insulating film;
forming a diffusion preventing film and a fourth metal film on the upper surface of the gate electrode of said first conductivity-type MIS region and the upper surface of the gate electrode of said second conductivity-type MIS region, respectively;
forming an alloy film by mutually reacting said third metal film of the gate electrode and said fourth metal film at said second conductivity-type MIS region through heat treatment to form a gate electrode of said third metal film and a gate electrode of said alloy film in said first conductivity-type MIS region and second conductivity-type MIS region, respectively,; and
removing said diffusion preventing film existing on the upper surface of the gate electrode of said first conductivity-type MIS region and the non-reactive fourth metal film remaining on the upper surface of the gate electrode of said second conductivity-type MIS region.

10. A method of manufacturing a semiconductor device comprising a CMIS transistor, the method comprising the steps of:
patterning a silicon film to become each gate electrode of a first conductivity-type MIS transistor and a second conductivity-type MIS transistor to a shape connected to each other above an isolation insulating film positioned at a boundary of the first conductivity-type MIS region and the second conductivity-type MIS region;
forming an insulating film for covering the gate electrodes;
exposing the upper surface of said gate electrodes by reducing the film thickness of said insulating film;
forming an etching mask including an opening positioned above said boundary, and removing only the silicon films of the gate electrodes positioned at said boundary using said etching mask so that said silicon film is isolated and face each other above said boundary;
completely filling a gap between the gate electrodes isolated from each other by an insulating film after removing said etching mask;
forming a first metal film and a second film on the upper surface of the gate electrode of said first conductivity-type MIS region and the upper surface of the gate electrode of said second conductivity-type MIS region, respectively;
forming a gate electrode of first metal silicide and a gate electrode of second metal silicide in said first conductivity-type MIS region and said second conductivity-type MIS region, respectively, through heat treatment; and
removing the non-reactive first metal film and the non-reactive second metal film.

11. A method of manufacturing a semiconductor device comprising a CMIS transistor, the method comprising the steps of:
patterning a metal film to become each gate electrode of a first conductivity-type MIS transistor and a second conductivity-type MIS transistor to a shape connecting to each other above an isolation insulating film positioned at a boundary of the first conductivity-type MIS region and the second conductivity-type MIS region;
forming an insulating film for covering the gate electrodes;
exposing the upper surface of said gate electrodes by reducing the film thickness of said insulating film;
forming an etching mask including an opening positioned above said boundary, and removing only the metal films of the gate electrodes positioned at said boundary using said etching mask so that said metal film is isolated and face each other above said boundary;
completely filling a gap between the gate electrodes isolated from each other by an insulating film after removing said etching mask;
forming a diffusion preventing film and a fourth metal film on the upper surface of the gate electrode of said first conductivity-type MIS region and the upper surface of the gate electrode of said second conductivity-type MIS region, respectively;
forming an alloy film by mutually reacting said third metal film of the gate electrode and said fourth metal film at said second conductivity-type MIS region through heat treatment to form a gate electrode of said third metal film and a gate electrode of said alloy film in said first conductivity-type MIS region and said second conductivity-type MIS region, respectively; and
removing said diffusion preventing film existing on the upper surface of the gate electrode of said first conductivity-type MIS region and the non-reactive fourth metal film remaining on the upper surface of the gate electrode of said second conductivity-type MIS region.

12. The method of manufacturing the semiconductor device according to claim 8, further comprising the steps of:
forming an inter-layer insulating film on the upper surfaces of said gate electrodes and the upper surface of the insulating film portion connecting the opposing surfaces of said gate electrodes to each other;
forming a connection hole reaching at least to the upper surfaces of said gate electrodes in said inter-layer insulating film at a region said gate electrodes face each other; and
filling a conductive film in said connection hole and electrically connecting said gate electrodes by way of said conductive film.

13. The method of manufacturing the semiconductor device according to claim 8, further comprising the steps of:
removing an insulating film portion connecting the opposing surfaces of said gate electrodes to each other;
filling a conducting film only to a removing part of said insulating film portion and electrically connecting said gate electrodes by way of said conductive film; and
forming an inter-layer insulating film on the upper surfaces of said gate electrodes and the upper surface of said conductive film.

14. A method of manufacturing a semiconductor device comprising a CMIS transistor, the method comprising the steps of:
patterning a material film to become gate electrodes of a first conductivity-type MIS transistor and a second conductivity-type MIS transistor to a shape connected to each other above an isolation insulating film positioned at a boundary of the first conductivity-type MIS region and the second conductivity-type MIS region;
forming source/drain regions through ion implantation;
forming an insulating film for covering the gate electrodes;
exposing the upper surfaces of said gate electrodes by reducing the film thickness of said insulating film;
reducing the film thickness of said gate electrodes so that the diffusion length of the gate electrode materials of both conductivity-type becomes less than the width of said isolation insulating film positioned at said boundary; and
forming gate electrodes made of different materials through heat treatment.

15. A method of manufacturing a semiconductor device comprising a CMIS transistor, the method comprising the steps of:
patterning a material film to become gate electrodes of a first conductivity-type MIS transistor and a second conductivity-type MIS transistor to a shape connected to each other above an isolation insulating film positioned at a boundary of the first conductivity-type MIS region and the second conductivity-type MIS region;
forming source/drain regions through ion implantation;
forming an insulating film for covering the gate electrodes;
exposing the upper surface of said gate electrodes by reducing the film thickness of said insulating film;
reducing the film thickness of said gate electrodes to less than half the width of said isolation insulating film positioned at said boundary; and
forming gate electrodes made of different materials through heat treatment.
